(19) United States
(12) Patent Application Publication
(10) Pub. No.: US 2026/0033042 A1
(43) Pub. Date: Jan. 29, 2026

(54) LIGHT EMITTING DEVICE AND LIGHT EMITTING APPARATUS INCLUDING THE SAME

(71) Applicant: SEOUL VIOSYS CO., LTD., Gyeonggi-do (KR)

(72) Inventor: Hyo Shik Choi, Gyeonggi-do (KR)

(21) Appl. No.: 19/274,696

(22) Filed: Jul. 21, 2025

Related U.S. Application Data
(60) Provisional application No. 63/674,838, filed on Jul. 24, 2024.
(60) Provisional application No. 63/693,280, filed on Sep. 11, 2024.

(51) Int. Cl. H10H 20/831; H10H 20/82

(52) U.S. Cl. CPC H10H 20/831; H10H 20/82

(57) ABSTRACT

A light emitting device and a light emitting apparatus including the same are disclosed. The light emitting device includes: a first conductivity type semiconductor layer, a second conductivity type semiconductor layer disposed above the first conductivity type semiconductor layer; and an active layer interposed between the first conductivity type semiconductor layer and the second conductivity type semiconductor layer, wherein the first conductivity type semiconductor layer includes a bunker layer in which the content of a first substance decreases such that a content profile of the first substance with respect to a depth of the bunker layer has a depressed shape.

### REFERENCE TO RELATED APPLICATIONS

The current application claims the benefit of U.S. Provisional Application Ser. No. 63/674,838, filed on 24 Jul. 2024 and U.S. Provisional Application Ser. No. 63/693,280, filed on 11 Sep. 2024, each of which is hereby incorporated by reference.

### TECHNICAL FIELD

The disclosed technology relates to a light emitting device and a light emitting apparatus including the same.

### BACKGROUND

A light emitting diode (LED) is a light emitting device that emits light when electric current is applied thereto. The light emitting diode is formed by growing epitaxial layers on a substrate and includes an N-type semiconductor layer, a P-type semiconductor layer, and an active layer interposed therebetween. An N-electrode pad is formed on the N-type semiconductor layer and a P-electrode pad is formed on the P-type semiconductor layer such that the light emitting diode is electrically connected to an external power source through the electrode pads. Here, electric current flows from the P-electrode pad to the N-electrode pad through the semiconductor layers.

Light emitting diodes can convert electrical signals into the form of light, such as infrared light, visible light, and ultraviolet light, using properties of compound semiconductors.

With improved luminous efficacy, light emitting diodes are being applied to various fields including displays and lighting devices and the size of the light emitting diodes has been reduced to realize mini-LEDs and micro-LEDs.

Display devices using light emitting diodes may be obtained by forming structures of red (R), green (G), and blue (B) light emitting diodes (LEDs) individually grown on a final substrate.

### SUMMARY OF THE DISCLOSURE

### Technical Problem

Embodiments of the disclosed technology may provide a light emitting device with improved luminous efficacy and a light emitting apparatus including the same.

Embodiments of the disclosed technology may provide a light emitting device, which may improve electrical characteristics by enabling low resistance at high current even when a chip is miniaturized, and a light emitting apparatus including the same.

### Technical Solution

In accordance with one aspect of the disclosed technology, a light emitting device includes a first conductivity type semiconductor layer, a second conductivity type semiconductor layer disposed above the first conductivity type semiconductor layer; and an active layer interposed between the first conductivity type semiconductor layer and the second conductivity type semiconductor layer, wherein the first conductivity type semiconductor layer may include a bunker layer in which the content of a first substance decreases such that a content profile of the first substance with respect to a depth of the bunker layer has a depressed shape.

In one embodiment, the bunker layer may be formed within 3 μm from the active layer.

In one embodiment, the bunker layer may form a first variable section having a variable content of the first substance and a second variable section spaced apart from the first variable section and having a variable content of the first substance.

In one embodiment, a change rate of the content of the first substance in the first variable section with respect to distance from the active layer may be different from a change rate of the content of the first substance in the second variable section with respect to distance from the active layer.

In one embodiment, the second variable section may be closer to the active layer than the first variable section.

In one embodiment, a difference between a maximum content of the first substance and a minimum content of the first substance in the second variable section may be greater than a difference between a maximum content of the first substance and a minimum content of the first substance in the first variable section.

In one embodiment, the bunker layer may further contain a second substance and a third substance, wherein the first substance may be aluminum, the second substance may be indium, and the third substance may be gallium.

In one embodiment, a difference between the content of the first substance and the content of the third substance in the bunker layer may be less than a difference between the content of the first substance and the content of the second substance in the bunker layer.

In one embodiment, a median value of the content of the first substance and the content of the second substance in the bunker layer may be included in a content region of the first substance in the first and second variable sections.

In one embodiment, at least two intersections where a difference between the content of the first substance and the content of the second substance is reversed may be formed within 3 μm from the bunker layer.

In one embodiment, the content of the first substance at the intersections may be greater than the content of the first substance in the bunker layer.

In one embodiment, the bunker layer may include a first region and a second region having different concentrations of a first conductivity type dopant.

In one embodiment, the first region may be closer to the active layer than the second region and may have a greater concentration of the first conductivity type dopant than the second region.

In one embodiment, the bunker layer may further include a third region and the first region may be disposed between the second region and the third region.

In one embodiment, the first region may have a greater concentration of the first conductivity type dopant than the third region.

In one embodiment, the third region may have a lower thickness than the second region.

In accordance with another aspect of the disclosed technology, a light emitting device includes: a first conductivity type semiconductor layer; a second conductivity type semiconductor layer disposed above the first conductivity type semiconductor layer; and an active layer interposed between the first conductivity type semiconductor layer and the second conductivity type semiconductor layer, wherein a content profile of each component with respect to depth from an upper surface of the second conductivity type semiconductor layer has a bunker in which the content of a first substance decreases in the first conductivity type semiconductor layer such that a content profile of the first substance with respect to a depth of the bunker has a depressed shape.

In one embodiment, the bunker may include first and second slopes each having a variable content of the first substance at opposite ends thereof.

In one embodiment, the first slope may have a different gradient than the second slope.

In one embodiment, the second slope may have a greater length than the first slope.

In one embodiment, the first slope may be closer to the active layer than the second slope.

In one embodiment, a content profile of the first substance and a content profile of the second substance may have at least two intersections within 3 μm from the bunker.

### Effects of the Invention

Embodiments of the disclosed technology may provide a light emitting device with improved luminous efficacy and a light emitting apparatus including the same.

Embodiments of the disclosed technology may provide a light emitting device, which may improve electrical characteristics by enabling low resistance at high current even when a chip is miniaturized, and a light emitting apparatus including the same.

### DESCRIPTION OF DRAWINGS

FIG. 1 is a cross-sectional view of a light emitting device according to one embodiment of the disclosed technology.

FIG. 2 is a cross-sectional view of epitaxial layers of the light emitting device shown in FIG. 1.

FIG. 3 is a content profile showing a depth-dependent component content distribution of the epitaxial layers shown in FIG. 2.

### DETAILED DESCRIPTION

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite to the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, or others, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

A light emitting device 100 according to an embodiment of the disclosed technology may include a first conductivity type semiconductor layer 110, a second conductivity type semiconductor layer 120 disposed above the first conductivity type semiconductor layer 110, and an active layer 130 interposed between the first conductivity type semiconductor layer 110 and the second conductivity type semiconductor layer 120. Hereinafter, exemplary embodiments of the disclosed technology will be described in more detail with reference to the accompanying drawings.

The first conductivity type semiconductor layer 110 is a semiconductor layer doped to become a first conductivity type and may be grown on a growth substrate. The growth substrate is a substrate for growth of semiconductor layers thereon and may have various configurations, for example, a gallium arsenide substrate.

The first conductivity type semiconductor layer 110 may include a phosphide or nitride semiconductor, such as (Al, Ga, In) P or (Al, Ga, In) N, and may be grown by a technique, such as MOCVD, MBE, HVPE, or the like. For example, the first conductivity type semiconductor layer 110 may be a phosphide semiconductor layer of (AlₓGa₍₁₋ₓ₎)_{0.5}In_{0.5}P doped to become a first conductivity type.

The first conductivity type semiconductor layer 110 may be doped with a first conductivity type dopant. For example, the first conductivity type dopant may include an n-type dopant. The n-type dopant may include at least one type of impurity, such as Si, Te, B, P, As, Sb, or others. The first conductivity type semiconductor layer 110 may include a single type of dopant or may include a plurality of types of dopants. For example, the first conductivity type semiconductor layer 110 may be doped with Si, Te, or a mixture of Si and Te. However, it should be understood that other implementations are possible and the first conductivity type semiconductor layer 110 may also be doped with an opposite conductivity type dopant including a p-type dopant. The p-type dopant may include at least one type of impurity, such as Mg, C (carbon), or others.

The second conductivity type semiconductor layer 120 may be a semiconductor layer disposed above the first conductivity type semiconductor layer 110 and may be doped to become a second conductivity type opposite to the first conductivity type.

The second conductivity type semiconductor layer 120 may include a phosphide or nitride semiconductor, such as (Al, Ga, In) P or (Al, Ga, In) N, and may be grown by a technique, such as MOCVD, MBE, or HVPE. For example, the second conductivity type semiconductor layer 120 may be a phosphide semiconductor layer of GaP doped to become a second conductivity type.

The second conductivity type semiconductor layer 120 may be doped with a second conductivity type dopant having a conductivity type opposite to the conductivity type of the first conductivity type semiconductor layer 120. By way of example, the second conductivity type dopant may include a p-type dopant. The p-type dopant may include at least one type of impurity, such as Mg, C (carbon), or others. For example, the second conductivity type semiconductor layer 120 may be doped with a p-type dopant including Mg, C (carbon), or others. The second conductivity type semiconductor layer 120 may be configured to include a Group III element. However, it should be understood that other implementations are possible and the second conductivity type semiconductor layer 120 may also be doped with an opposite conductivity type dopant including an n-type dopant. The n-type dopant may include at least one type of impurity, such as Si, Te, B, P, As, Sb, or others.

The active layer 130 is a light emitting layer interposed between the first conductivity type semiconductor layer 110 and the second conductivity type semiconductor layer 120, and may have various configurations. The active layer 130 may include a phosphide or nitride semiconductor, such as (Al, Ga, In) P or (Al, Ga, In) N, and may be grown by a technique, such as MOCVD, MBE, or HVPE. For example, the active layer 130 may have any one composition of InₓGa_{y}Al_{z}P and InₓGa_{y}P.

The active layer 130 may be formed to a thickness of 150 nm to 250 nm.

In addition, the active layer 130 may include a single quantum-well structure (QW) including at least two barrier layers and at least one well layer. Alternatively, the active layer 130 may include a multi-quantum well structure (MQW) including a plurality of barrier layers and a plurality of well layers.

The wavelength of light emitted from the active layer 130 may be adjusted by controlling the composition ratio of materials constituting the well layers. The well layers may include the same element in common, for example, indium (In). The well layers may have a composition represented by any one of InₓGa_{y}Al_{z}P (x+y+z=1) and InₓGa_{y}P (x+y=1) and may be formed to a thickness of 3 to 7 nm.

The barrier layers may have a composition of InₓGa_{y}Al_{z}P. Here, x, y, and z may satisfy a relation: x*0.8≤y+z≤x*1.2 or x+y+z=1. In addition, z may be in the range of 0.15 to 0.4 (0.15≤z≤0.4).

The barrier layers may be formed as undoped layers to improve quality of a thin film or may be formed as n-type doped layers to improve electron implantation.

The barrier layers may have a greater thickness than the well layers, preferably a thickness of 10 nm or more.

When the well layers and barrier layers are formed in pairs, the active layer 130 may include 10 to 40 pairs of well layers and barrier layers. Light emitted from the active layer 130 may have a peak wavelength in the range of 600 nm to 700 nm.

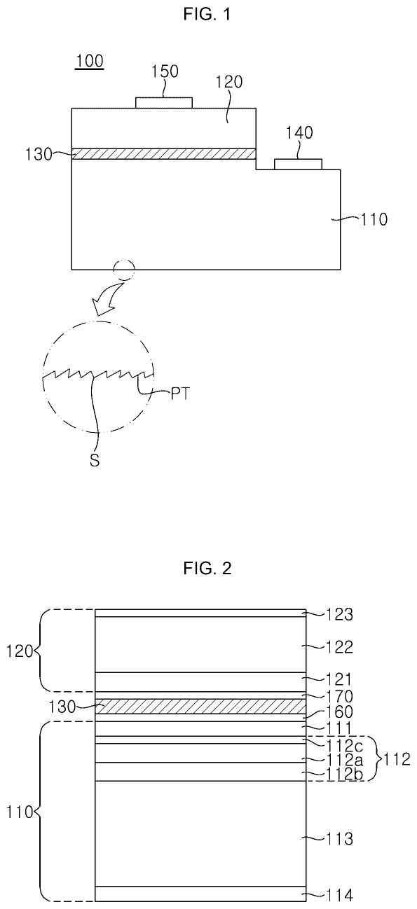

Referring to FIG. 1, the second conductivity type semiconductor layer 120 may be partially etched such that the first conductivity type semiconductor layer 110 is at least partially exposed. Accordingly, the light emitting device 100 may include a first electrode 140 disposed on an exposed surface of the first conductivity type semiconductor layer 110 and a second electrode 150 disposed on one surface of the second conductivity type semiconductor layer 120. Electric power may be applied to the light emitting device 100 through the first electrode 140 and second electrode 150. However, it should be understood that other implementations are possible. Alternatively, the first conductivity type semiconductor layer 110 may be partially etched such that the second conductivity type semiconductor layer 120 is at least partially exposed. In this embodiment, the light emitting device 100 may include a second electrode 150 disposed on an exposed surface of the second conductivity type semiconductor layer 120 and a first electrode 140 disposed on one surface of the first conductivity type semiconductor layer 110. Electric power may be applied to the light emitting device 100 through the first electrode 140 and the second electrode 150. Although FIG. 1 illustrates one example of the light emitting device 100 configured in a flip-chip form, it should be understood that other implementations are possible and the light emitting device according to the disclosed technology may be realized in various ways, such as a vertical type, a horizontal type, or others.

In the disclosed technology, the first conductivity type semiconductor layer 110 may include multiple layers. For example, the first conductivity type semiconductor layer 110 may include a first-1 conductivity type sub-semiconductor layer 113 and a first-2 conductivity type sub-semiconductor layer 111.

The first-1 conductivity type sub-semiconductor layer 113 may include a phosphide of (Al, Ga, In) P or a nitride of (Al, Ga, In) N, and may be doped with a first conductivity type dopant. For example, the first-1 conductivity type sub-semiconductor layer 113 may be a phosphide semiconductor layer having a composition of (AlₓGa₍₁₋ₓ₎)_{0.5}In_{0.5}P. Here, x may range from 0.8 to 0.6.

The first-1 conductivity type sub-semiconductor layer 113 may be doped with an n-type dopant to generate and supply electrons. The n-type dopant may include Si, without being limited thereto. Alternatively, Te may also be used as the n-type dopant.

The first-1 conductivity type sub-semiconductor layer 113 may have a doping concentration in the range of 1E18 to 1E20 atoms/cm³ as a main semiconductor layer.

A surface layer 114 of the first-1 conductivity type sub-semiconductor layer 113 may have a textured surface S. Referring to FIG. 1, the surface layer 114 may be partially etched to form irregularities PT on the surface S. The surface layer 114 may have a higher doping concentration than the main semiconductor layer.

The first-2 conductivity type sub-semiconductor layer 111 may be disposed between the first first-1 conductivity type sub-semiconductor layer 113 and the active layer 130.

The first-2 conductivity type sub-semiconductor layer 111 may be composed of InₓAl₍₁₋ₓ₎P doped with a first conductivity type dopant. Here, x may be in the range of 0.4 to 0.6 (0.4≤x≤0.6) and the first-2 conductivity type sub-semiconductor layer 111 may have a doping concentration of 7E17 atoms/cm³ to 3E18 atoms/cm³ and a thickness of 200 nm or more.

The first-2 conductivity type sub-semiconductor layer 111 may be a clad layer that has a higher energy bandgap than the well layers of the active layer 130 to allow electrons and holes to recombine within the active layer 130. In addition, the first-2 conductivity type sub-semiconductor layer 111 may have a higher energy bandgap or a higher aluminum content than the first-1 conductivity type sub-semiconductor layer 113. Thus, the rate of electron implantation into the well layers may be regulated. The first-2 conductivity type sub-semiconductor layer 111 may include a different dopant than the first-1 conductivity type sub-semiconductor layer 113. Thus, a region close to the active layer 130 may include a substance having higher ionization energy to provide higher electron affinity, thereby enabling more efficient generation of electrons. The first-2 conductivity type sub-semiconductor layer 111 may use a Te source, which is an n-type dopant, as the first conductivity type dopant. The use of the Te source may secure good photometric properties.

On the other hand, the light emitting device 100 may further include an electron regulation layer 160 between the first-2 conductivity type sub-semiconductor layers 111 and the active layer 130.

The electron regulation layer 160 may be an undoped InAlGaP layer that regulates the rate at which electrons reach the active layer 130 to obtain a fast recombination rate. The thickness of the electron regulation layer 160 may be adjusted together with the thickness of a diffusion barrier layer 170 described below.

The electron regulation layer 160 has a lower doping concentration than the first conductivity type semiconductor layer 110 and may be formed of InₓGa_{y}Al_{z}P. Here, x, y, and z may satisfy a relation: x*0.8≤y+z≤x*1.2 or x+y+z=1. In addition, z may be in the range of 0.15 to 0.4 (0.15≤z≤0.4). As the electron regulation layer 160 has such an Al composition, the electron regulation layer may improve light extraction efficiency by preventing light generated by the light emitting device 100 from being absorbed by the electron regulation layer 160.

In addition, the light emitting device 100 may further include a diffusion barrier layer 170 disposed between the second conductivity type semiconductor layer 120 and the active layer 130. The diffusion barrier layer 170 may be an undoped InAlGaP layer that regulates the rate at which holes reach the active layer 130. Further, the diffusion barrier layer 170 may serve to protect the active layer 130 from damage due to diffusion caused by doping of the second conductivity type semiconductor layer 120 with the second conductivity type dopant.

That is, the diffusion barrier layer 170 may be disposed to prevent excessive diffusion of the second conductivity type dopant into the active layer 130 and may be formed of InₓGa_{y}Al_{z}P. Here, x, y, and z may satisfy the relation: x*0.8≤y+z≤x*1.2 or x+y+z=1. Further, z may be in the range of 0.15 to 0.4 (0.15≤z≤0.4).

The diffusion barrier layer 170 may be an undoped layer and may have a lower doping concentration than the second conductivity type semiconductor layer 120. Further, the diffusion barrier layer 170 may be formed through combination of three Group III elements.

The diffusion barrier layer 170 may have a thickness of 50 nm or more to effectively prevent diffusion of the second conductivity type dopant into the active layer 130 while improving reliability and preventing deterioration in low-current applied voltage and reverse voltage current characteristics. Further, the diffusion barrier layer 170 is preferably formed to a thickness of 400 nm or less.

On the other hand, the second conductivity type semiconductor layer 120 may also be composed of multiple layers. For example, the second conductivity type semiconductor layer 120 may include a second-1 conductivity type sub-semiconductor layer 122 and a second-2 conductivity type sub-semiconductor layer 121.

The second-1 conductivity type sub-semiconductor layer 122 may be a GaP layer doped with a second conductivity type dopant (such as Mg or C). The second 1-1 conductivity type sub-semiconductor layer 122 may be formed to a thickness of 0.5 μm to 10 μm depending on the structure as a main semiconductor layer for formation and supply of holes.

As the second conductivity type dopant, the second-1 conductivity type sub-semiconductor layer 122 may use either Mg or C (carbon) or may simultaneously use both substances through simultaneous implantation of both substances. Mg may be doped in a doping concentration of 2E17 to 4E18 atoms/cm³. The second-1 conductivity type sub-semiconductor layer 122 may have a thickness of 400 nm or more to allow supply of sufficient holes while realizing current dispersion.

Furthermore, the second-1 conductivity type sub-semiconductor layer 122 may include at least one Group III element.

The second-2 conductivity type sub-semiconductor layer 121 may be disposed between the second-1 conductivity type sub-semiconductor layer 122 and the active layer 130.

The second-2 conductivity type sub-semiconductor layer 121 may be an InAlP layer doped with a second conductivity type dopant and may be configured to act as a clad layer that prevents electron overflow. Mg or C (CBr4) may be used as the second conductivity type dopant.

Specifically, the second-2 conductivity type sub-semiconductor layer 121 may be composed of InₓAl₍₁₋ₓ₎P doped with a second conductivity type dopant. Here, x may range from 0.4 to 0.6 (0.4≤x≤0.6) and the second-2 conductivity type sub-semiconductor layer 121 may have a doping concentration of 8E17 atoms/cm³ or less.

The second-2 conductivity type sub-semiconductor layer 121 may have a thickness of 300 nm to 500 nm. Preferably, the second-2 conductivity type sub-semiconductor layer 121 has a greater thickness than the active layer 130.

The second-2 conductivity type sub-semiconductor layer 121 may be composed of two group III elements and may have a higher energy bandgap than layers disposed under and on the second-2 conductivity type sub-semiconductor layer.

Alternatively, the second-2 conductivity type sub-semiconductor layer 121 may have the highest energy bandgap among the layers constituting the light emitting device 100. Alternatively, the second-2 conductivity type sub-semiconductor layer 121 may have a lower index of refraction than the layers disposed under and on the second-2 conductivity type sub-semiconductor layer. Alternatively, the second-2 conductivity type sub-semiconductor layer 121 may have the lowest index of refraction among the layers constituting the light emitting device 100. This structure may prevent non-radiative recombination due to migration of electrons. Furthermore, the light emitting device may improve light extraction efficiency due to arrangement of the second-2 conductivity type sub-semiconductor layer 121 having a low index of refraction.

The second conductivity type semiconductor layer 120 may further include a second-3 conductivity type sub-semiconductor layer 123. The second-3 conductivity type sub-semiconductor layer 123 may be a contact layer disposed on the second conductivity type sub-semiconductor layer 122 and contacting the second electrode 150.

The second-3 conductivity type sub-semiconductor layer 123 may be an ohmic contact layer for obtaining ohmic properties with the second electrode 150. The second-third conductivity type sub-semiconductor layer 123 may be a GaP layer doped with a second conductivity type dopant.

The second-3 conductivity type sub-semiconductor layer 123 may have a high doping concentration (for example, 7E17 atoms/cm³ or more) for ohmic contact with the second electrode 150. The second-3 conductivity type sub-semiconductor layer 123 may have a higher doping concentration than the second-1 conductivity type sub-semiconductor layer 122, thereby improving the ohmic properties of the second electrode 150.

For the second-3 conductivity type sub-semiconductor layer 123, Mg or C (carbon) may be used as the second conductivity type dopant. As the second conductivity type dopant, the second-3 conductivity type sub-semiconductor layer 123 may use either Mg or C (carbon) or may simultaneously use both substances through simultaneous implantation of both substances.

The second-3 conductivity type sub-semiconductor layer 123 may have a thickness of 100 nm or less. Since the second-3 conductivity type sub-semiconductor layer 123 has a relatively high doping concentration, the second-3 conductivity type sub-semiconductor layer 123 has defects due to the dopants. Thus, as the thickness of the second-3 conductivity type sub-semiconductor layer 123 increases, light absorption may occur due to these defects, thereby causing deterioration in optical efficiency. Accordingly, the second-3 conductivity type sub-semiconductor layer 123 may be formed to a thickness of 100 nm or less to prevent deterioration in optical efficiency due to light absorption. The second-3 conductivity type sub-semiconductor layers 123 is an optional configuration that may be omitted.

On the other hand, the first conductivity type semiconductor layer 110 may further include a bunker layer 112 to increase a residence time of electrons traveling toward the active layer 130.

The bunker layer 112 may be a layer in which the content of a first substance decreases in the first conductivity type semiconductor layer 110 such that a content profile of the first substance with respect to the depth of the bunker layer 112 has a depressed shape. The bunker layer 112 may be disposed between the first-1 conductivity type sub-semiconductor layer 113 and the first-2 conductivity type sub-semiconductor layer 111. The first substance may be one of substances constituting the first conductivity type semiconductor layer 110. Here, the substances may refer to components constituting the first conductivity type semiconductor layer 110 except for the first conductivity type dopant.

For example, the first conductivity type semiconductor layer 110 may include a first substance, a second substance, a third substance, and a fourth substance, in which the first substance may be aluminum (AI), the second substance may be indium (In), the third substance may be gallium (Ga), and the fourth substance may be phosphorus (P). The first substance may have a relatively low atomic weight among the substances constituting the first conductivity type semiconductor layer 110. The bunker layer 112 may also include the first substance, the second substance, the third substance, and the fourth substance.

That is, the bunker layer 112 may have a lower content of the first substance than other regions within the first conductivity type semiconductor layer 110.

The bunker layer 112 may include the same material as the first-1 conductivity type sub-semiconductor layer 113 and may have a different composition ratio than the first-1 conductivity type sub-semiconductor layer 113.

For example, the bunker layer 112 may have a composition of (AlₓGa₁₋ₓ)_{0.5}In_{0.5}P, where x is in the range of 0.3 to 0.5.

The content of the first substance in the bunker layer 112 may be less than the content of the first substance in the first-1 conductivity type sub-semiconductor layer 113. Here, the first substance may be Al.

Further, the content ratio of the first substance to the third substance (content of the first substance/content of the third substance) in the bunker layer 112 may be less than the content ratio of the first substance to the third substance in the first-1 conductivity type sub-semiconductor layer 113. Here, the first substance may be Al and the third substance may be Ga.

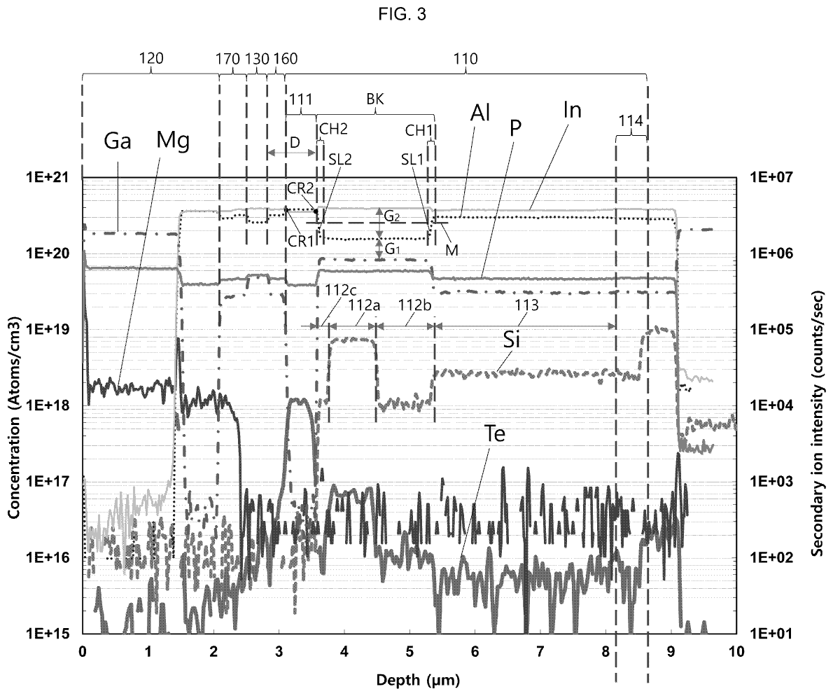

The bunker layer 112 may be formed within 3 μm from the active layer 130. That is, referring to FIG. 3, a distance D between the boundary of the bunker layer 112 and the boundary the active layer 130 may be less than or equal to 3 μm.

The bunker layer 112 may have a lower content of the first substance than other layers adjacent thereto and may form a first variable section CH1 having a variable content of the first substance and a second variable section CH2 spaced apart from the first variable section CH1 and having a variable content of the first substance.

Referring to FIG. 3, the first variable section CH1 has a variable content of the first substance and may be a section where the content of the first substance is increased in a direction away from the active layer 130. The second variable section CH2 has a variable content of the first substance and may be a section in which the content of the first substance is decreased in a direction away from the active layer 130. The second variable region CH2 may be closer to the active layer 130 than the first variable region CH1.

As shown in FIG. 3, the content profile of the first substance with respect to the depth of the bunker layer 112 may be depicted as a puddle shape (depressed shape) by the first variable section CH1 and the second variable section CH2. Here, the depth may refer to a distance from an upper surface of the second conductivity type semiconductor layer 120 in a direction from the upper surface of the second conductivity type semiconductor layer 120 toward the active layer 130.

The first variable section CH1 and the second variable section CH2 may have the same thickness or different thicknesses.

The first variable section CH1 may have a maximum value and a minimum value of the content of the first substance at opposite ends thereof. Similarly, the second variable section CH2 may have a maximum value and a minimum value of the content of the first substance at opposite ends thereof.

The maximum value of the content of the first substance in the first variable section CH1 may be the same as or different from the maximum value of the content of the first substance in the second variable section CH2. The minimum value of the content of the first substance in the first variable section CH1 may be the same as or different from the minimum value of the content of the first substance in the second variable section CH2.

For example, a difference between the maximum value and the minimum value of the content of the first substance in the second variable section CH2 may be greater than a difference between the maximum value and the minimum value of the content of the first substance in the first variable section CH1.

A middle section located between the first variable section CH1 and the second variable section CH2 may be a section in which the content of the first substance is constant within a certain range. Although there is a slight variation in content of the first substance, the middle section may be understood as a section having a constant content of the first substance with small fluctuations within a certain range. Within the bunker layer 112, the minimum value of the content of the first substance may range from 0.55 times to 0.6 times the maximum value thereof.

A change rate of the content of the first substance in the first variable section CH1 with respect to distance from the active layer 130 may be different from a change rate of the content of the first substance in the second variable section CH2 with respect to distance from the active layer 130.

The change rate of the content of the first substance in the first variable section CH1 may be determined by the thickness of the first variable section CH1 and the difference between the maximum value and the minimum value of the content of the first substance at the boundaries of the first variable section CH1. The change rate of the content of the first substance in the second variable section CH2 may be determined by the thickness of the second variable section CH2 and the difference between the maximum value and the minimum value at the boundaries of the second variable section CH2. Since the content of the first substance in the first variable section CH1 increases with depth, a content gradient of the first substance may have a positive value, and since the content of the first substance in the second variable section (CH2) decreases with depth, the Al content gradient may have a negative value. Here, the change rate of the content of the first substance may refer to an absolute value of the content gradient of the first substance.

Referring again to FIG. 3, a difference G1 between the content of the first substance and the content of the third substance in the bunker layer 112 may be less than a difference G2 between the content of the first substance and the content of the second substance in the bunker 112.

In addition, a median value of the content of the first substance and the content of the second substance in the bunker layer 112 may be included in the content range of the first substance in the first and second variable sections CH1, CH2. Referring to FIG. 3, the median value of the content of the first substance and the content of the second substance in the bunker layer 112 is indicated by an imaginary dashed line M, which may intersect the content region of the first substance in the first variable section CH1. That is, the median value of the content of the first substance and the content of the second substance in the bunker layer 112 may be included in the content region of the first substance in the first variable section CH1. Similarly, the dotted line M may intersect the content region of the first substance in the second variable region CH2. That is, the median value of the content of the first substance and the content of the second substance in the bunker layer 112 may be included in the content region of the first substance in the second variable region CH2.

Referring again to FIG. 3, at least two intersections CR1, CR2 where a difference between the content of the first substance and the content of the second substance is reversed may be formed within 3 μm from the bunker layer 112. The two intersections CR1, CR2 may be formed in the first-2 conductivity type sub-semiconductor layer 111.

In a region between the two intersections CR1, CR2, the content of the first substance may be greater than the content of the second substance. Outside the region between the two intersections CR1, CR2, the content of the first substance may be less than the content of the second substance.

The content of the first substance at the intersections CR1, CR2 may be greater than the content of the first substance in the bunker layer 112.

On the other hand, the bunker layer 112 may include a first region 112a and a second region 112b having different concentrations of the first conductivity type dopant. Referring to FIG. 3, the first conductivity type dopant is Si. However, it should be understood that other implementations are possible.

The first region 112a may be a region closer to the active layer 130 than the second region 112b. The first region 112a may be closer to the active layer 130 than the second region 112b.

The first region 112a may be a region doped with a high concentration of the first conductivity type dopant and may be a contact layer that contacts the first electrode 140. That is, the first region 112a may be exposed by partially etching the second conductivity type semiconductor layer 120, the active layer 130, and the first conductivity type semiconductor layer 110 and the first electrode 140 may contact the exposed first region 112a. The first region 112a may have a high doping concentration of, for example, 5E18 atoms/cm³ or more, to act as the contact layer. The first region 112a may be formed to a thickness of about 500 nm. However, it should be understood that other implementations are possible and the contact layer may be formed in other regions of the first conductivity type semiconductor layer 110 to contact the first electrode 140.

The concentration of the first conductivity type dopant in the first region 112a may be greater than the concentration of the first conductivity type dopant in the second region 112b. The concentration of the first conductivity type dopant in the first region 112a may be greater than the concentration of the first conductivity type dopant in the first-1 conductivity type sub-semiconductor layer 113.

The second region 112b is a region disposed between the first region 112a and the first-1 conductivity type sub-semiconductor layer 113, in which the concentration of the first conductivity type dopant in the second region 112b may be less than the concentration of the first conductivity type dopant in the first-1 conductivity type sub-semiconductor layer 113.

The second region 112b may have the same thickness as or a greater thickness than the first region 112a.

The bunker layer 112 may further include a third region 112c.

The first region 112a may be disposed between the second region 112b and the third region 112c. That is, the third region 112c may be closer to the active layer 130 than the first region 112a and the second region 112b.

The concentration of the first conductivity type dopant in the first region 112a may be greater than the concentration of the first conductivity type dopant in the third region 112c. The concentration of the first conductivity type dopant in the third region 112c may be the same as or similar to the concentration of the first conductivity type dopant in the second region 112b.

The third region 112c may be doped with a low concentration of the first conductivity type dopant and may be a current spreading layer to improve current spreading by increasing resistance due to the low doping concentration.

The third region 112c may have a lower thickness than the first and second regions 112a, 112b. The thickness of the third region 112c may be less than or equal to 0.2 times the thickness of each of the first and second regions 112a, 112b.

FIG. 3 shows a content profile depicting a content distribution of each component (Ga, Al, In, P, Te, Si, Mg) with respect to depth from the upper surface toward the lower side of the second conductivity type semiconductor layer 120.

The bunker layer 112 may correspond to a bunker BK in the profile of FIG. 3. The bunker BK may refer to a section in the content distribution profile where the content of the first substance in the first conductivity type semiconductor layer 110 decreases in the form of a depression (puddle shape).

The bunker BK may be formed within 3 μm from a region corresponding to the active layer 130. The bunker BK may include first and second slopes SL1, SL2 each having a variable content of the first substance at opposite ends thereof.

The first slope SL1 corresponds to an inclination of the content profile of the first substance in the first variable section CH1 of the bunker BK and the second slope SL2 may correspond to an inclination of the content profile of the first substance in the second variable section CH2 of the bunker BK. The second slope SL2 may be closer to the active layer 130.

Referring to FIG. 3, the first variable section CH1 is a region where the content of the first substance increases with depth, and the inclination of the first slope SL1 may have a positive value. The second variable section CH2 is a region where the content of the first substance decreases with depth, and the inclination of the second slope SL2 may have a negative value.

An absolute value of the inclination of each of the first slope SL1 and the second slope SL2 may be defined as a gradient. Here, the gradient of the first slope SL1 may be different from the gradient of the second slope SL2. For example, the second slope SL2 may have a greater gradient than the first slope SL1.

The first slope SL1 may have a different length than the second slope SL2. Here, the length of the first slope SL1 may be determined by a thickness of the first variable section CH1 forming the first slope SL1 and a change in the content of the first substance in the first variable section CH1. Similarly, the length of the second slope SL2 may be determined by a thickness of the second variable section CH2 forming the second slope SL2 and a change in the content of the first substance in the second variable section CH2.

For example, the length of the second slope SL2 may be longer than the length of the first slope SL1.

An imaginary dashed line M passing through a center of each of the content profile of the second substance and the content profile of the first substance in the bunker BK may intersect each of the content profiles of the first substance in the first variable section CH1 and the second variable section CH2.

In addition, a difference G1 between the content of the first substance and the content of the third substance in the bunker BK may be less than a difference G2 between the content of the first substance and the content of the second substance in the bunker BK.

Within 3 μm from the bunker BK, the content profile of the first substance and the content profile of the second substance may have at least two intersections CR1, CR2. Before and after the intersections CR1, CR2, a difference between the content of the first substance and the content of the second substance may be reversed.

The two intersections CR1, CR2 may be formed in the first-2 conductivity type sub-semiconductor layer 111. Furthermore, the intersections CR1, CR2 may be formed at a position higher than the bunker BK.

The light emitting device 100 described above may be provided singularly or in plural to form a light emitting apparatus. The light emitting apparatus includes at least one light emitting device 100 and may be a display panel, a display device, a lighting device, or others. In particular, the light emitting device 100 described above may be one of LEDs constituting pixels (PX) of the display device and may be applied as a RED LED, for example.

The light emitting device 100 according to the disclosed technology enables low resistance at high currents even when the chip is miniaturized, thereby improving electrical characteristics.

Although some exemplary embodiments have been described herein with reference to the accompanying drawings, it should be understood that various modifications and changes can be made by those skilled in the art or by a person having ordinary knowledge in the art without departing from the spirit and scope of the invention, as defined by the claims and equivalents thereto.

Therefore, the scope of the invention should be defined by the appended claims and equivalents thereto instead of being limited to the detailed description of the disclosed technology.

1. A light emitting device comprising:
a first conductivity type semiconductor layer;
a second conductivity type semiconductor layer disposed above the first conductivity type semiconductor layer; and
an active layer interposed between the first conductivity type semiconductor layer and the second conductivity type semiconductor layer,
wherein the first conductivity type semiconductor layer includes a bunker layer in which a content of a first substance decreases such that a content profile of the first substance with respect to a depth of the bunker layer has a depressed shape.

2. The light emitting device according to claim 1, wherein the bunker layer is formed within 3 μm from the active layer.

3. The light emitting device according to claim 1, wherein the bunker layer forms a first variable section having a first variable content of the first substance and a second variable section spaced apart from the first variable section and having a second variable content of the first substance.

4. The light emitting device according to claim 3, wherein a change rate of the first variable content of the first substance in the first variable section with respect to distance from the active layer is different from a change rate of the second variable content of the first substance in the second variable section with respect to distance from the active layer.

5. The light emitting device according to claim 3, wherein the second variable section is closer to the active layer than the first variable section.

6. The light emitting device according to claim 3, wherein a difference between a maximum value and a minimum value of the second variable content of the first substance in the second variable section is greater than a difference between a maximum value and a minimum value of the first variable content of the first substance in the first variable section.

7. The light emitting device according to claim 1, wherein:
the bunker layer further includes a second substance and a third substance;
the first substance is aluminum, the second substance is indium, and the third substance is gallium; and
a difference between the content of the first substance and a content of the third substance in the bunker layer is less than a difference between the content of the first substance and a content of the second substance in the bunker layer.

8. The light emitting device according to claim 7, wherein a median value of the content of the first substance and the content of the second substance in the bunker layer is included in a content region of the first substance in a first variable section and a second variable section in the bunker layer.

9. The light emitting device according to claim 1, wherein:
the bunker layer further includes a second substance;
the first substance is aluminum and the second substance is indium; and
at least two intersections where a difference between a content of the first substance and a content of the second substance is reversed are formed within 3 μm from the bunker layer.

10. The light emitting device according to claim 9, wherein the content of the first substance at the at least two intersections is greater than the content of the first substance in the bunker layer.

11. The light emitting device according to claim 1, wherein the bunker layer includes a first region and a second region having different concentrations of a first conductivity type dopant.

12. The light emitting device according to claim 11, wherein the first region is closer to the active layer than the second region and has a greater concentration of the first conductivity type dopant than a concentration of the first conductivity type dopant in the second region.

13. The light emitting device according to claim 11, wherein the bunker layer further includes a third region and the first region is disposed between the second region and the third region.

14. The light emitting device according to claim 13, wherein the first region has a greater concentration of the first conductivity type dopant than a concentration of the first conductivity type dopant in the third region.

15. The light emitting device according to claim 13, wherein the third region has a lower thickness than a thickness of the second region.

16. A light emitting device comprising:
a first conductivity type semiconductor layer;
a second conductivity type semiconductor layer disposed above the first conductivity type semiconductor layer; and
an active layer interposed between the first conductivity type semiconductor layer and the second conductivity type semiconductor layer,
wherein a content profile of each component with respect to a depth from an upper surface toward a lower side of the second conductivity type semiconductor layer comprises a bunker in which a content of a first substance decreases in the first conductivity type semiconductor layer such that a content profile of the first substance with respect to the depth of the bunker has a depressed shape.

17. The light emitting device according to claim 16, wherein the bunker includes first and second slopes each having a variable content of the first substance at opposite ends thereof, and the first slope has a different gradient than a gradient of the second slope.

18. The light emitting device according to claim 17, wherein the second slope has a greater length than a length of the first slope.

19. The light emitting device according to claim 17, wherein the first slope is closer to the active layer than the second slope.

20. The light emitting device according to claim 16, wherein:
the bunker further includes a second substance;
the first substance is aluminum and the second substance is indium; and
the content profile of the first substance and a content profile of the second substance have at least two intersections within 3 μm from the bunker.
